(19) United States
(12) Patent Application Publication
(10) Pub. No.: US 2026/0010669 A1
(43) Pub. Date: Jan. 8, 2026

(54) GENERATING DEVICE FOR SCAN CAPTURE CONSTRAINT AND GENERATING METHOD THEREOF

(71) Applicants: Global Unichip Corporation, Hsinchu (TW); Taiwan Semiconductor Manufacturing Company, Ltd., Hsinchu (TW)

(72) Inventors: Chen-Yuan Kao, Hsinchu (TW); Yi-Hsuan Chiu, Hsinchu (TW)

(73) Assignees: Global Unichip Corporation, Hsinchu (TW); Taiwan Semiconductor Manufacturing Company, Ltd., Hsinchu (TW)

(21) Appl. No.: 18/796,210

(22) Filed: Aug. 6, 2024

(30) Foreign Application Priority Data
Jul. 2, 2024 (TW) 113124633

(51) Int. Cl. G06F 30/17

(52) U.S. Cl. CPC G06F 30/17

(57) ABSTRACT

A generating device and a generating method for scan capture constraint are provided. The generating method for scan capture constraint includes: performing a clock mapping operation according to clock information, a netlist, and first function constraint information to generate a clock mapping report; performing a timing constraint generating operation according to the first function constraint information, the clock mapping report, and a wrapper cell report to generate scan timing constraint information; and performing an automatic test pattern generation constraint generating operation according to the scan timing constraint information, a hard macro instance list, and test mode configuration information to generate automatic test pattern constraint information.

### CROSS-REFERENCE TO RELATED APPLICATION

This application claims the priority benefit of Taiwan application serial no. 113124633, filed on Jul. 2, 2024. The entirety of the above-mentioned patent application is hereby incorporated by reference herein and made a part of specification.

### BACKGROUND OF THE INVENTION

### Field of the Invention

The invention relates to the field of electronic design automation (EDA), and in particular to a generating device for scan capture constraint and a generating method thereof.

### Description of Related Art

In the field of circuit design, design for testability (DFT) engineers are committed to designing high-quality SDC (synopsys design constraint) constraint files for timing analysis and automatic test pattern generation (ATPG) within a limited time.

Generally, DFT engineers use the function timing constraint to design the scan timing constraint for full-speed capture (also known as at-speed capture, AC). However, due to issues such as the mismatch between the full-speed capture scan clock and the function clock, the additional full-speed capture scan path, and the design scope difference between timing analysis and automatic test pattern generation, DFT engineers still need to perform actions such as complex modifications, timing, and design structure analysis for function timing constraint to generate usable full-speed capture scan timing constraint. Accordingly, significant design time is needed, thus significantly affecting design timing quality.

### SUMMARY OF THE INVENTION

Accordingly, the invention provides a generating device for scan capture constraint and a generating method thereof that may significantly reduce the generation time of timing constraint for full-speed capture scan (AC scan) and automatic test pattern generation, thus effectively improving design timing quality and test pattern generation efficiency.

A generating method for scan capture constraint of the invention includes: performing a clock mapping operation according to clock information, a netlist, and first function constraint information to generate a clock mapping report; performing a timing constraint generating operation according to the first function constraint information, the clock mapping report, and a wrapper cell report to generate scan timing constraint information; and performing an automatic test pattern generation constraint operation according to the scan timing constraint information, a hard macro instance list, and test mode configuration information to generate automatic test pattern constraint information.

A generating device for scan capture constraint of the invention includes a memory element and a controller. The memory element stores first function constraint information, clock information, a netlist, a wrapper cell report, a hard macro instance list, and test mode configuration information. The controller is configured to execute the generating method for scan capture constraint.

Based on the above, the generating device for scan capture constraint and the generating method thereof provided by the invention may perform the clock mapping operation, the timing constraint generating operation, and the automatic test pattern generation constraint generating operation sequentially on the first function constraint information to generate the automatic test pattern constraint information that may be used for full-speed capture scanning and automatic test pattern generation to reduce the generation time of timing constraint.

In order to make the aforementioned features and advantages of the disclosure more comprehensible, embodiments accompanied with figures are described in detail below.

### BRIEF DESCRIPTION OF THE DRAWINGS

FIG. 1 shows a flowchart of a generating method for scan capture constraint of an embodiment of the invention.

FIG. 2 shows a flowchart of a generating method for scan capture constraint of an embodiment of the invention.

FIG. 3 shows a flowchart of performing a clock mapping operation of an embodiment of the invention.

FIG. 4A shows a schematic diagram of the issue of undefined clock of an embodiment of the invention.

FIG. 4B shows a schematic diagram of the issue of multiple source clocks of an embodiment of the invention.

FIG. 4C shows a schematic diagram of the issue of not being able to inherit a function clock of an embodiment of the invention.

FIG. 5 shows a schematic diagram of updating a mapped clock in SDC function constraint information of an embodiment of the invention.

FIG. 6 shows a schematic diagram of removing an unused clock from SDC function constraint information of an embodiment of the invention.

FIG. 7 shows a schematic diagram of performing a scan structure constraint update operation of an embodiment of the invention.

FIG. 8 shows a schematic diagram of a generating device for scan capture constraint of an embodiment of the invention.

### DESCRIPTION OF THE EMBODIMENTS

A portion of the embodiments of the disclosure is described in detail hereinafter with reference to figures. In the following, the same reference numerals in different figures should be considered to represent the same or similar elements. The embodiments are only a part of the invention, and do not disclose all possible implementation modes of the invention. Rather, the embodiments are merely examples within the scope of the invention.

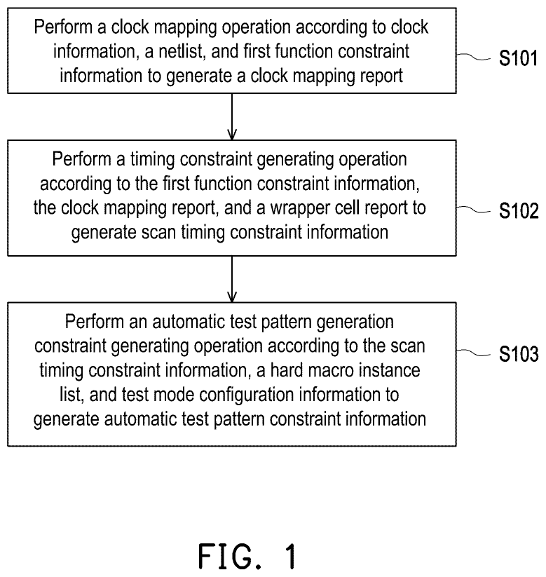

Please refer to FIG. 1. FIG. 1 shows a flowchart of a generating method for scan capture constraint of an embodiment of the invention. In step S101, a clock mapping operation may be performed according to clock information, a netlist, and first function constraint information to generate a clock mapping report. Here, a function clock in the first function constraint information may be mapped to a scan clock, so as to facilitate DFT engineers to solve the issue of mismatch between the function clock and the full-speed capture scan clock. The clock information in the present embodiment may be on-chip clock (OCC) information. The first function constraint information may be TCL (tool command language) function constraint information.

Next, in step S102, a timing constraint generating operation may be performed according to the first function constraint information, the clock mapping report, and a wrapper cell report to generate scan timing constraint information. Here, unused timing constraint may be removed based on the clock mapping report obtained in step S101, and the timing constraint associated with the wrapper cell report may be updated. The scan timing constraint information in the present embodiment may be, for example, timing constraint information for full-speed capture scanning.

Lastly, in step S103, an automatic test pattern generation constraint generating operation may be performed according to the scan timing constraint information, a hard macro instance list, and test mode configuration information to generate automatic test pattern constraint information. Here, the timing constraint associated with automatic test pattern generation may be added to the scan timing constraint information obtained in step S102.

As a result, the generating method for scan capture constraint of the invention may perform the clock mapping operation, the timing constraint generating operation, and the automatic test pattern generation constraint generating operation sequentially on the first function constraint information (for example, TCL function constraint information) to generate the automatic test pattern constraint information so as to reduce generation time of timing constraint.

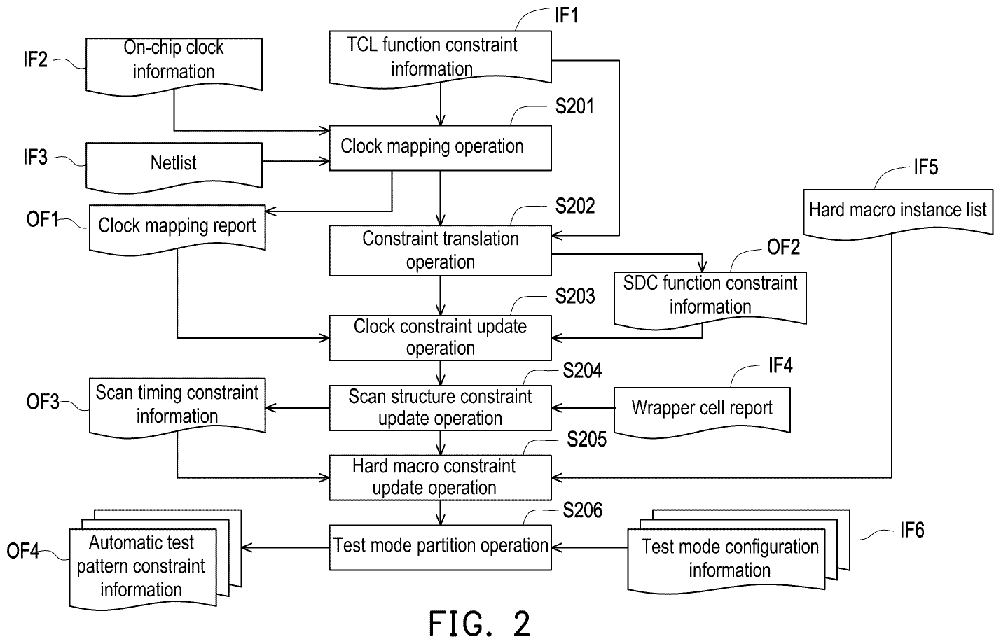

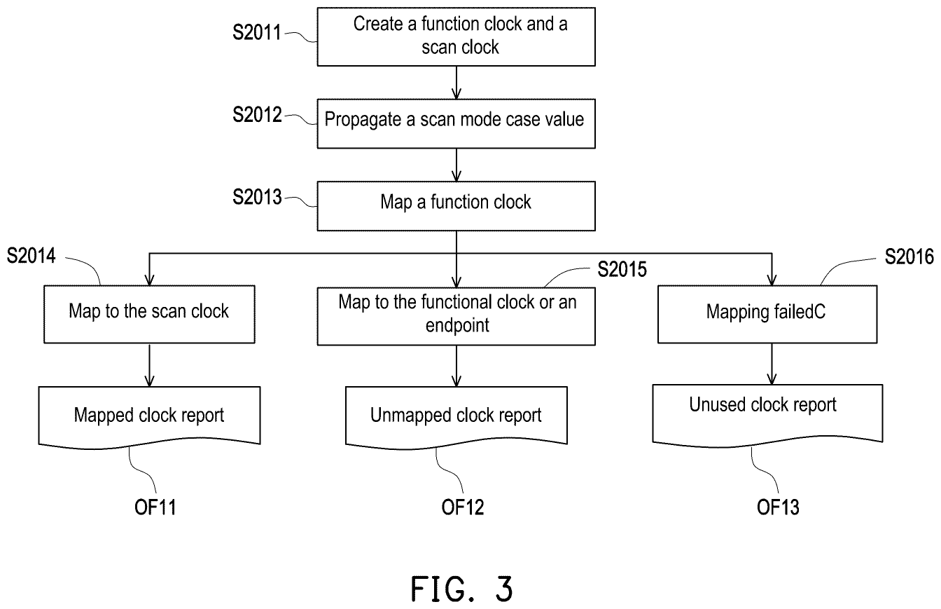

Please refer to FIG. 2 below. FIG. 2 shows a flowchart of a generating method for scan capture constraint of an embodiment of the invention. In step S201, TCL function constraint information IF1 (i.e., first function constraint information), on-chip clock information IF2, and a netlist IF3 are received, and a clock mapping operation is performed accordingly. In particular, the clock mapping operation is to map a function clock in the on-chip clock information IF2, the netlist IF3, and the TCL function constraint information IF1 to a scan clock. Please refer to FIG. 2 and FIG. 3 simultaneously, wherein FIG. 3 shows a flowchart of performing a clock mapping operation of an embodiment of the invention. In step S2011, the action of creating a function clock and a scan clock may be performed. In step S2012, the action of scan mode case value propagation may be performed. In step S2013, the action of mapping the function clock may be performed. If the function clock is mapped to the scan clock, step S2014 is performed, and a mapped clock report OF11 is generated according to the mapping relationship between all mapped function clocks and the scan clock. If the function clock is mapped to a function clock or an endpoint, step S2015 is performed, and an unmapped clock report OF12 is generated according to all function clocks mapped to the function clock or the endpoint. If the function clock mapping fails, step S2016 is performed, and an unused clock report OF13 is generated according to all function clocks that failed to be mapped.

In the present embodiment, a clock mapping report OF1 contains but is not limited to the mapped clock report OF11, the unmapped clock report OF12, and the unused clock report OF13. In particular, the function clock recorded in the unmapped clock report OF12 is not mapped to the scan clock (that is, the function clock recorded in the unmapped clock report OF12 does not have a corresponding scan clock). In this regard, DFT engineers may further confirm the reason why the function clock is not mapped to the scan clock. In particular, common reasons include incorrect timing constraint setting and the need to increase the corresponding scan clock manually, for example.

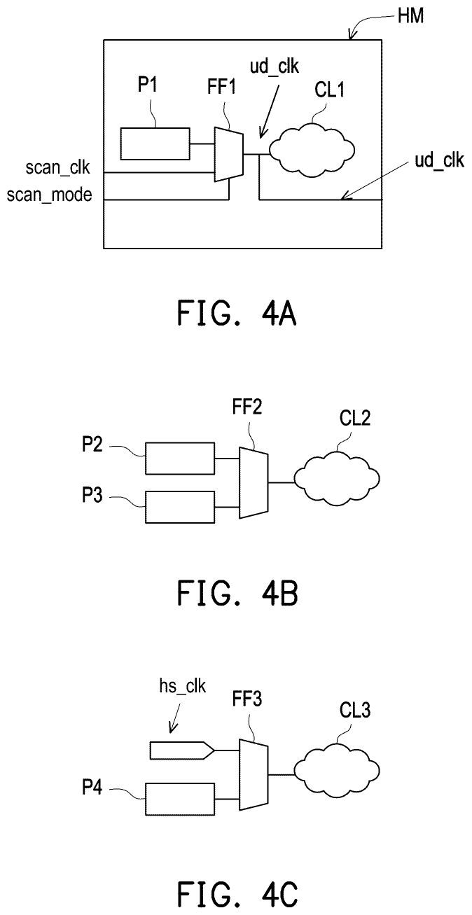

It should also be mentioned that, DFT engineers may use the clock mapping report OF1 to solve the mismatch issue between the function clock and the full-speed capture scan clock. The difference in clock structure between the function clock and the full-speed capture scan clock may result in the issue of undefined clock as shown in FIG. 4A, the issue of multiple source clocks as shown in FIG. 4B, and the issue of not being able to inherit function clock as shown in FIG. 4C. DFT engineers may learn about the above issues via the clock mapping report OF1.

Please refer to FIG. 4A. FIG. 4A shows a schematic diagram of the issue of undefined clock of an embodiment of the invention. A hard macro HM in FIG. 4A includes a phase-locked loop P1 (PLL), a flip-flop FF1, and a combinational logic circuit CL1. The flip-flop FF1 may receive a scan clock scan_clk and a scan mode signal scan_mode from outside the hard macro HM. Regarding the issue of undefined clock, since the clock ud_clk inside the hard macro HM is defined in the timing library, the clock ud_clk inside the hard macro HM is often undefined in the subsequent automatic test pattern generation process. In this regard, DFT engineers may redefine the clock ud_clk inside the hard macro HM.

Please refer to FIG. 4B. FIG. 4B shows a schematic diagram of the issue of multiple source clocks of an embodiment of the invention. FIG. 4B includes phase-locked loops P2 and P3, a flip-flop FF2, and a combinational logic circuit CL2. Regarding the issue of multiple source clocks, only one of the source clocks is used when a scan test is performed. In this regard, DFT engineers may identify the desired source clock (for example, the source clock provided by the phase-locked loop P2) and correspondingly delete the erroneous path associated with the undesired source clock. That is, DFT engineers may correspondingly delete the path associated with the phase-locked loop P3.

Please refer to FIG. 4C. FIG. 4C shows a schematic diagram of the issue of not being able to inherit the function clock of an embodiment of the invention. FIG. 4C includes a phase-locked loop P4, a flip-flop FF3, and a combinational logic circuit CL3. Regarding the issue of not being able to inherit the function clock, due to testing constraints, the function clock (for example, the clock provided by a primary input hs_clk) may not be inherited as the scan clock while the primary input hs_clk exceeds the performance of automatic test equipment (ATE). In this regard, DFT engineers may choose a high-speed clock from the phase-locked loop P4 as the scan clock.

Next, please refer to FIG. 2 again. After the clock mapping operation of S201 is performed, the timing constraint generating operation may be performed next. In particular, the timing constraint generating operation includes a constraint translation operation (step S202), a clock constraint update operation (step S203), and a scan structure constraint update operation (step S204) performed sequentially.

In step S202, the TCL function constraint information IF1 is received, and a constraint translation operation is performed accordingly. In particular, the constraint translation operation is to translate TCL function constraint information into SDC (synopsys design constraint) function constraint information OF2 (that is, the second function constraint information). In order to avoid the issue that tools that perform scan tests or other subsequent tests do not support function constraint based on TCL, the TCL function constraint information may be translated into SDC function constraint information in step S202. In particular, the stringency of function constraint based on SDC is also higher than the stringency of function constraint based on TCL.

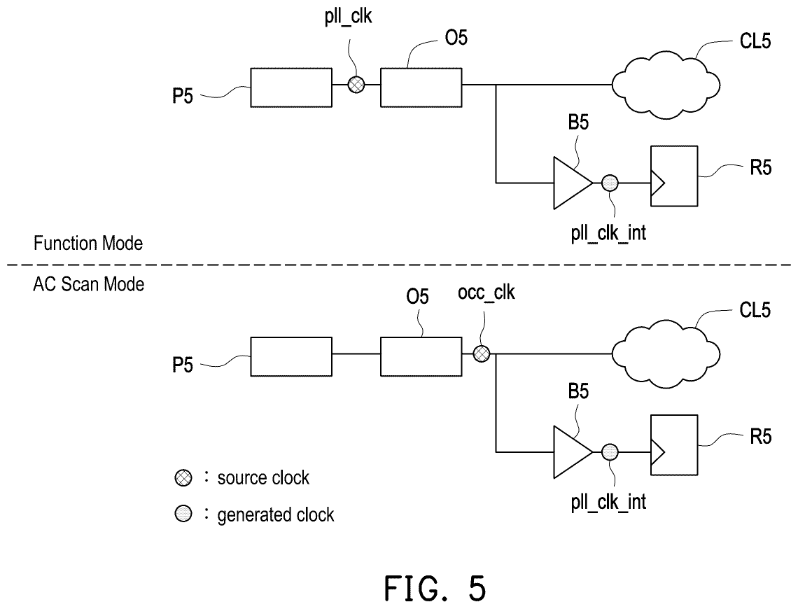

In step S203, the clock mapping report OF1 and the SDC function constraint information OF2 are received, and the clock constraint update operation is performed accordingly. In particular, the clock constraint update operation includes updating the mapped clock in the SDC function constraint information OF2 based on the clock mapping report OF1. Here, please refer to FIG. 2, FIG. 3, and FIG. 5 simultaneously, wherein FIG. 5 shows a schematic diagram of updating the mapped clock in the SDC function constraint information of an embodiment of the invention. FIG. 5 includes a phase-locked loop P5, an on-chip clock circuit O5, a buffer gate B5, a combinational logic circuit CL5, and a register R5. In function mode, a source clock pll_clk and a generated clock pll_clk_int are contained. In full-speed capture scan mode (AC scan mode), the source clock occ_clk and the generated clock pll_clk_int are contained.

The mapped clock report OF11 in the present embodiment is configured to record the mapping relationship between the function clock and the scan clock obtained in step S201. For example, the source clock pll_clk in function mode is mapped to the source clock occ_clk in full-speed capture scan mode. Therefore, in step S203, the source clock pll_clk in the SDC function constraint information OF2 may be updated to the source clock occ_clk. For example, the SDC function constraint information OF2 records the following information: set_false_path-from ppl_clk-to R5 (the path between the source clock ppl_clk to the register R5 is set as the false path). In step S203, this information may be updated to set_false_path-from ooc_clk-to R5 (the path between the source clock occ_clk and the register R5 is set as the false path).

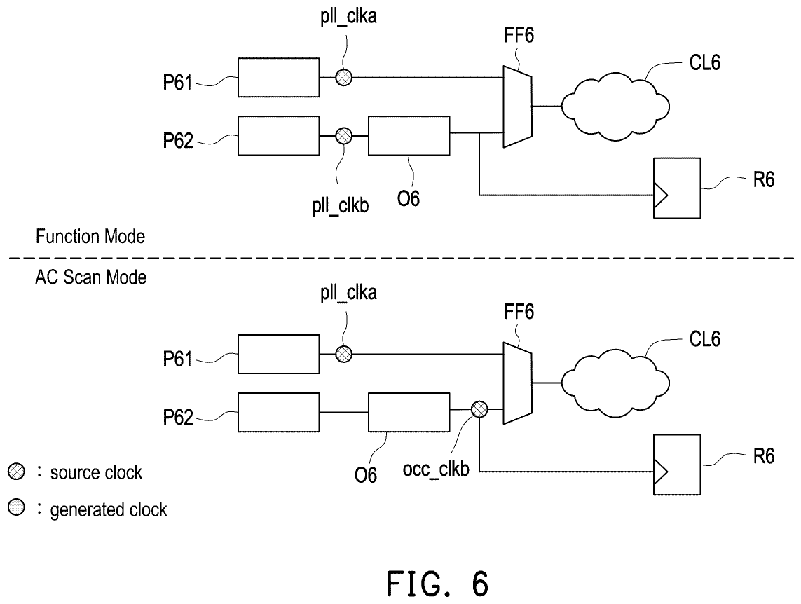

In addition, the clock constraint update operation also includes removing the unused clock in the SDC function constraint information OF2 based on the clock mapping report OF1. Here, please refer to FIG. 2, FIG. 3, and FIG. 6 simultaneously, wherein FIG. 6 shows a schematic diagram of removing the unused clock in the SDC function constraint information of an embodiment of the invention. FIG. 6 includes phase-locked loops P61 and P62, an on-chip clock circuit O6, a flip-flop FF6, a combinational logic circuit CL6, and a register R6. In function mode, source clocks pll_clka and pll_clkb are contained. In full-speed capture scan mode (AC scan mode), source clocks pll_clka and occ_clkb are contained.

The unused clock report OF13 in the present embodiment is configured to record the function clock that failed to be mapped in step S201. For example, the source clock pll_clka recorded in the unused clock report OF13 is used in the function mode and is not used in the scan mode. Therefore, in step S203, the information about the source clock pll_clka in the SDC function constraint information OF2 may be removed. For example, the information about the source clock pll_clka in the SDC function constraint information OF2 is as follows: set_false_path-from pll_clka-to R6 (the path between the source clock pll_clka to the register R6 is set as the failed path) and set_false_path-from pll_clka-to pll_clkb (the path between the source clock pll_clka to the source clock pll_clkb is set as the failed path). In step S203, the information about the source clock pll_clka may be removed from the SDC function constraint information OF2.

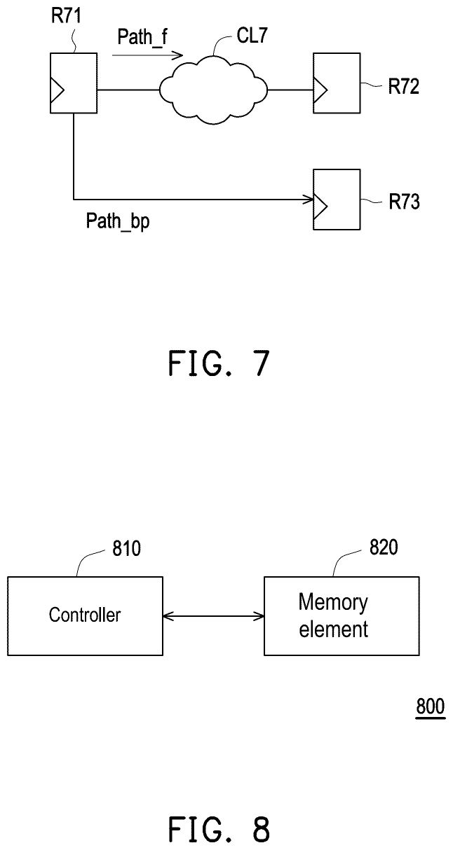

In step S204, a wrapper cell report IF4 is received, and a scan structure constraint update operation is performed accordingly. In particular, the scan structure constraint update operation is to add a timing constraint of a scan shift path to the SDC function constraint information OF2 of the updated and/or removed data in step S203 based on the wrapper cell report IF4 to generate the scan timing constraint information OF3. Here, please refer to FIG. 2 and FIG. 7 simultaneously, wherein FIG. 7 shows a schematic diagram of performing a scan structure constraint update operation of an embodiment of the invention. FIG. 7 includes temporary registers R71, R72, and R73 and a combinational logic circuit CL7.

In step S204, based on the wrapper cell report IF4, a failed path Path_f may be avoided, and a scan shift path Path_bp may be added correspondingly. In particular, the failed path Path_f is a path from the register R71 to the register R72 via the combinational logic circuit CL7. The scan shift path Path_bp is the path from the register R71 to the register R73. Therefore, in step S204, the timing constraint on the scan shift path Path_bp may be added to the SDC function constraint information OF2.

Lastly, after the scan structure constraint update operation of S204 is completed, an automatic test pattern generation constraint generating operation may be performed next. In particular, the automatic test pattern generation constraint generating operation includes a hard macro constraint update operation (step S205) and a test mode partition operation (step S206) performed sequentially.

In step S205, the scan timing constraint information OF3 and a hard macro instance list IF5 are received, and a hard macro constraint update operation is performed accordingly. In particular, the hard macro instance list IF5 contains but is not limited to the scope and content of performing a scan test. The hard macro constraint update operation is to update the timing constraint in the scan timing constraint information OF3 based on the hard macro instance list IF5. For example, the hard macro constraint update operation is to update the timing constraint associated with the hard macro instance list IF5 in the scan timing constraint information OF3.

In step S206, a test mode configuration information IF6 is received, and a test mode partition operation is performed accordingly. In particular, the test pattern configuration information IF6 contains but is not limited to the modes and the related constraints of automatic test pattern generation. The test mode partition operation is to delete the timing constraint belonging to the untested block in the scan timing constraint information OF3 updated in step S205 based on the test mode configuration information IF6, and add or update the timing constraint associated with automatic test pattern generation in the scan timing constraint information OF3 to generate automatic test pattern constraint information OF4.

Based on the above, the generating method for scan capture constraint provided by the invention may perform the clock mapping operation (step S201), the timing constraint generating operation (step S202 to step S204), and the automatic test pattern generation constraint generating operation (step S205 and step S206) sequentially on the TCL function constraint information IF1 to generate the automatic test pattern constraint information OF4 that may be used for full-speed capture scanning and automatic test pattern generation, so as to significantly reduce the generation time of timing constraint.

Please refer to FIG. 8 below. FIG. 8 shows a schematic diagram of a generating device for scan capture constraint of an embodiment of the invention. A generating device 800 includes a controller 810 and a memory element 820. The controller 810 and the memory element 820 are coupled to each other. In particular, the memory element 820 may be configured to store first function constraint information, clock information, a netlist, a wrapper cell report, a hard macro instance list, and test mode configuration information. The controller 810 may read the first function constraint information, the clock information, the netlist, the wrapper cell report, the hard macro instance list, and the test mode configuration information via the memory element 820 and accordingly perform the generating method for scan capture constraint shown in FIG. 1 and FIG. 2.

The execution details of the generating method for scan capture constraint have been described in detail in the above embodiments and are therefore not repeated here.

In the present embodiment, the memory element 820 may also be configured to store temporary data generated by the calculation process of the controller 810. In terms of hardware architecture, the controller 810 may be a processor having computing capabilities. Or, the controller 810 may be a hardware circuit designed via Hardware Description Language (HDL) or any other digital circuit design method well known to those having ordinary knowledge in the art, and implemented via a field-programmable gate array (FPGA), a complex programmable logic device (CPLD), or an application-specific integrated circuit (ASIC). In addition, the storage element 820 may be various types of random-access memory (RAM), read-only memory (ROM), etc., but is not limited thereto.

Based on the above, the generating device for scan capture constraint and the generating method thereof of the invention can, via the clock mapping operation, the timing constraint generating operation, and the automatic test pattern generation constraint generating operation performed sequentially, reduce the generation time of timing constraint and effectively improve design timing quality and test pattern generation efficiency.

Although the invention has been described with reference to the above embodiments, it will be apparent to one of ordinary skill in the art that modifications to the described embodiments may be made without departing from the spirit of the disclosure. Accordingly, the scope of the disclosure is defined by the attached claims not by the above detailed descriptions.

What is claimed is:

1. A generating method for scan capture constraint, comprising:
performing a clock mapping operation according to clock information, a netlist, and first function constraint information to generate a clock mapping report;
performing a timing constraint generating operation according to the first function constraint information, the clock mapping report, and a wrapper cell report to generate scan timing constraint information; and
performing an automatic test pattern generation constraint generating operation according to the scan timing constraint information, a hard macro instance list, and test mode configuration information to generate automatic test pattern constraint information.

2. The generating method of claim 1, wherein the step of performing the clock mapping operation comprises:
mapping a function clock in the clock information, the netlist, and the first function constraint information to a scan clock.

3. The generating method of claim 1, wherein the clock mapping report comprises a mapped clock report, an unmapped clock report, and an unused clock report.

4. The generating method of claim 1, wherein the timing constraint generating operation comprises a constraint translation operation, a clock constraint update operation, and a scan structure constraint update operation performed sequentially.

5. The generating method of claim 4, wherein the step of performing the constraint translation operation comprises:
translating the first function constraint information into second function constraint information.

6. The generating method of claim 5, wherein the step of performing the clock constraint update operation comprises:
updating a mapped clock in the second function constraint information based on the clock mapping report; and
removing an unused clock in the second function constraint information based on the clock mapping report.

7. The generating method of claim 6, wherein the step of performing the scan structure constraint update operation comprises:
adding a timing constraint of a scan shift path to the second function constraint information based on the wrapper cell report to generate the scan timing constraint information.

8. The generating method of claim 1, wherein the automatic test pattern generation constraint generating operation comprises a hard macro constraint update operation and a test mode partition operation performed sequentially.

9. The generating method of claim 8, wherein the step of performing the hard macro constraint update operation comprises:
updating a timing constraint in the scan timing constraint information based on the hard macro instance list.

10. The generating method of claim 9, wherein the step of performing the test mode partition operation comprises:
deleting a timing constraint belonging to an untested block in the scan timing constraint information based on the test mode configuration information; and
adding or updating a timing constraint associated with an automatic test pattern generation in the scan timing constraint information based on the test mode configuration information to generate the automatic test pattern constraint information.

11. A generating device for scan capture constraint, comprising:
a memory element storing first function constraint information, clock information, a netlist, a wrapper cell report, a hard macro instance list, and test mode configuration information; and
a controller coupled to the memory element and configured to:
perform a clock mapping operation according to the clock information, the netlist, and the first function constraint information to generate a clock mapping report;
perform a timing constraint generating operation according to the first function constraint information, the clock mapping report, and the wrapper cell report to generate scan timing constraint information; and
perform an automatic test pattern generation constraint generating operation according to the scan timing constraint information, the hard macro instance list, and the test mode configuration information to generate automatic test pattern constraint information.

12. The generating device of claim 11, wherein the controller is configured to:
map a function clock in the clock information, the netlist, and the first function constraint information to a scan clock.

13. The generating device of claim 11, wherein the controller is configured to:
translate the first function constraint information into second function constraint information.

14. The generating device of claim 13, wherein the controller is configured to:
update a mapped clock in the second function constraint information based on the clock mapping report; and
remove an unused clock in the second function constraint information based on the clock mapping report.

15. The generating device of claim 14, wherein the controller is configured to:
add a timing constraint of a scan shift path to the second function constraint information based on the wrapper cell report to generate the scan timing constraint information.

16. The generating device of claim 11, wherein the controller is configured to:
update a timing constraint in the scan timing constraint information based on the hard macro instance list.

17. The generating device of claim 16, wherein the controller is configured to:
delete a timing constraint belonging to an untested block in the scan timing constraint information based on the test mode configuration information; and
add or update a timing constraint associated with an automatic test pattern generation in the scan timing constraint information based on the test mode configuration information to generate the automatic test pattern constraint information.
